(19) United States
(12) Patent Application Publication
(10) Pub. No.: US 2010/0017692 A1
(43) Pub. Date: Jan. 21, 2010

(54) METHOD AND APPARATUS FOR CYCLIC REDUNDANCY CHECK IN COMMUNICATION SYSTEM

(75) Inventor: Chang-Hyun KWAK, Seoul (KR)

Correspondence Address: THE FARRELL LAW FIRM, LLP, 290 Broadhollow Road, Suite 210E, Melville, NY, 11747, US

(73) Assignee: SAMSUNG ELECTRONICS CO., LTD., Suwon-si (KR)

(21) Appl. No.: 12/505,137

(22) Filed: Jul. 17, 2009

(30) Foreign Application Priority Data
Jul. 17, 2008 (KR) 10-2008-0069442

(51) Int. Cl. H03M 13/09; G06F 11/10

(52) U.S. Cl. 714/807; 714/E11.032

(57) ABSTRACT

A method for performing a Cyclic Redundancy Check (CRC) in a communication system is provided. An input message is divided into a predetermined number of segments. The CRC is performed on each segment to generate a CRC code of each segment. Polynomial addition is performed on CRC codes of respective segments to obtain a CRC code of the input message.

### PRIORITY

This application claims priority under 35 U.S.C. §119(a) to a Korean patent application filed in the Korean Intellectual Property Office on Jul. 17, 2008 and assigned Serial No. 10-2008-0069442, the entire disclosure of which is incorporated herein by reference.

### BACKGROUND OF THE INVENTION

1. Field of the Invention

The present invention relates generally to a method and an apparatus for Cyclic Redundancy Check (CRC) in a communication system, and more particularly to a method and an apparatus for shortening a decoding time by dividing a reception signal into N segments to perform a CRC.

2. Description of the Related Art

Generally, in a wireless channel environment of a communication system, errors are typically generated causing information loss. These errors are due to various factors such as multipath interference, shadowing, radio wave attenuation, time-varying noise, interference, and fading. Such information loss distorts a transmission signal and deteriorates an entire performance of the communication system.

Accordingly, in the conventional art, various error control techniques are provided depending on the characteristic of a channel in order to reduce the information loss. Basic error control techniques use an error detection code and an error correction code. The technique using the error detection code allows a receiver to recognize whether an error occurs while information passes through a wireless channel environment by adding an error detection code to the information to be transmitted. The technique using the error correction code recovers a portion of information where an error has occurred.

A widely used method that uses the error judgment code is Cyclic Redundancy Check (CRC). The CRC contracts a general (n, k) cyclic code and uses the same.

FIG. 1 illustrates data encoded after a CRC code is added to an information message to be transmitted. Assuming the length of an information message m(x) before the CRC code is added is k, a message polynomial for the m(x) may be expressed as in Equation (1) below.

m(x)=mₖ₋₁x^{k-1}+mₖ₋₂x^{k-2}+ . . . +m₁x+m₀ (1)

In Equation (1), mₖ is each bit of the information message. In the information message, mₖ₋₁ is transmitted initially and m₀ is transmitted last.

Equation (2) represents a generator polynomial of a cyclic code.

g(x)=gᵣx^{r}+gᵣ₋₁x^{r-1}+gᵣ₋₂x^{r-2}+ . . . +g₁x+g₀ (2)

In Equation (2) gᵣ represents whether an information message input terminal S0 is connected with each shift factor, and has a value of 0 or 1.

Generally, a systematical encoding of the cyclic code is performed using a method of generating a code polynomial, as in Equation (3), below by adding a remainder polynomial generated by dividing a message polynomial expressed in Equation (1) by a generator polynomial expressed in Equation (2), to a message polynomial multiplied by xᵣ.

Equation (3) below represents a code polynomial generated using the cyclic encoding method.

c(x)=mₖ₋₁xⁿ⁻¹+mₖ₋₂xⁿ⁻²+ . . . +m₁x^{n-k+1}+m₀x^{n-k}+pᵣ₋₁x^{r-1}+pᵣ₋₂x^{r-2}+ . . . +p₀ (3)

In Equation (3), pᵣ₋₁, . . . , p₀ is a CRC code added after cyclic encoding.

FIG. 2 illustrates a conventional serial CRC encoder/decoder. Referring to FIG. 2, the serial CRC encoder/decoder forms a Linear Feedback Shift Register (LFSR) and includes a plurality of registers 200, 202, 204, . . . , 208 for storing an intermediate value during an encoding operation. The LFSR also includes a plurality of switches 210, 212, 214, . . . , 218 representing whether there exists a connection line depending on a coefficient of a generator polynomial g(x). When an information message is input initially, the serial CRC encoder/decoder connects switches 230 and 240 with S0 to perform encoding/decoding. When a last bit m₀ of an information message is input, the serial CRC encoder/decoder connects the switches 230 and 240 with S1 to output parity bits stored in the registers 200, 202, 204, and 208.

The above-described CRC encoder/decoder is limited in that a great amount of time is consumed for encoding/decoding because the CRC encoder/decoder processes an information message one bit by one bit. Therefore, a parallel encoding/decoding structure has been suggested for processing N bits at a time in order to reduce a delay time, instead of processing the information message one bit by one bit.

FIG. 3 illustrates a conventional parallel CRC encoder/decoder. Referring to FIG. 3, the parallel CRC encoder/decoder includes a combinational network 300 for generating a next parity bit and registers 310, 312, 314, 316, and 318 for storing a parity bit after every bit input. Accordingly, the parallel CRC encoder/decoder stores previous N bit input results, determines a next parity bit through combination of current N bit inputs and the stored parity bit, and stores a next parity bit again.

Assuming that an entire encoding time of the serial CRC encoder/decoder is n, the parallel CRC encoder/decoder may reduce an encoding/decoding time by n/N by processing the N bits at a time, but is still limited in that it must sequentially process the input information message N bits by N bits.

### SUMMARY OF THE INVENTION

The present invention has been made to address at least the above problems and/or disadvantages and to provide at least the advantages described below. Accordingly, one aspect of the present invention provides a method and an apparatus for CRC in a communication system.

Another aspect of the present invention provides a method and an apparatus for improving a data processing rate by reducing a delay time caused by encoding/decoding of CRC in a communication system.

A further aspect of the present invention provides a method and an apparatus for reducing a delay time caused by CRC by dividing a reception signal into N segments and performing the CRC on the divided N segments.

According to one aspect of the present invention, a method for performing a Cyclic Redundancy Check (CRC) in a communication system is provided. An input message is divided into a predetermined number of segments. The CRC is performed on each segment to generate a CRC code of each segment. Polynomial addition is performed on the CRC codes of the predetermined number of segments to obtain a CRC code of the input message.

According to another aspect of the present invention, an apparatus for performing a CRC in a communication system is provided. The apparatus includes a segmentation unit for dividing an input message into a predetermined number of segments. The apparatus also includes a CRC generator for each segment for generating a CRC code of each segment. Additionally, the apparatus includes a Galois Field (GF) adder for performing polynomial addition on the CRC codes of the predetermined number of segments to obtain a CRC code of the input message.

### BRIEF DESCRIPTION OF THE DRAWINGS

The above and other aspects, features and advantages of the present invention will be more apparent from the following detailed description when taken in conjunction with the accompanying drawings in which:

FIG. 1 is a diagram illustrating data encoded after a CRC code is added to an information message to be transmitted;

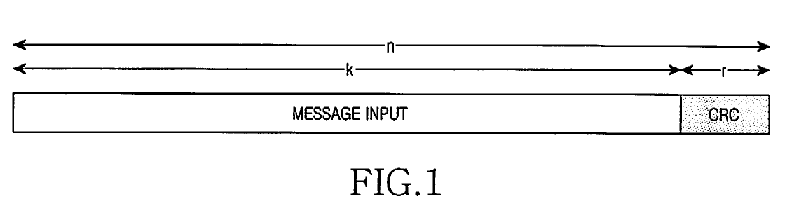

FIG. 2 is a diagram illustrating a conventional serial CRC encoder/decoder;

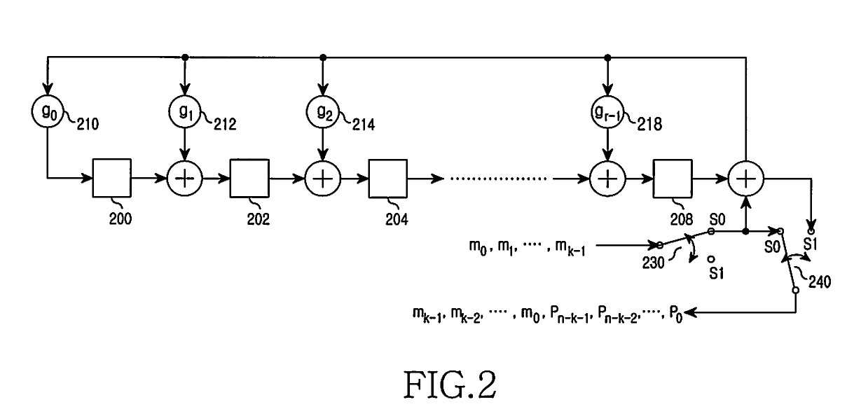

FIG. 3 is a diagram illustrating a conventional parallel CRC encoder/decoder;

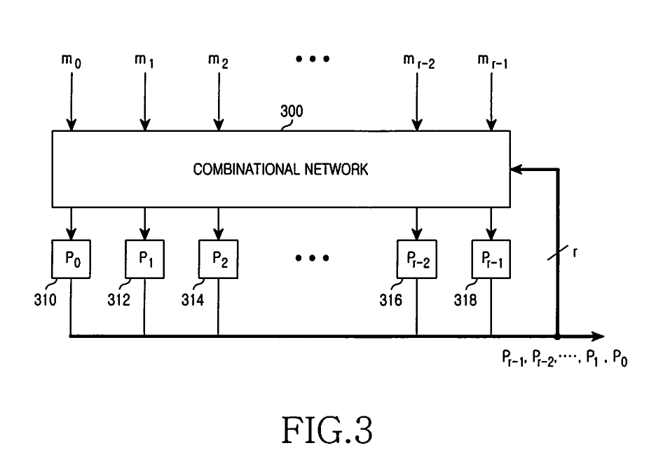

FIG. 4 is a diagram illustrating an information message divided into four segments, according to an embodiment of the present invention;

FIG. 5 is a diagram illustrating a technique of generating a CRC code of an entire information message using divided segments, according to an embodiment of the present invention;

FIG. 6 is a diagram illustrating a technique of generating a CRC code of an entire information message using divided segments, according to another embodiment of the present invention;

FIG. 7 is a block diagram illustrating a CRC decoder in a communication system, according to an embodiment of the present invention; and

FIG. 8 is a flowchart illustrating a CRC decoding methodology in a communication system, according to an embodiment of the present invention.

### DETAILED DESCRIPTION OF EMBODIMENTS OF THE PRESENT INVENTION

Embodiments of the present invention are described in detail with reference to the accompanying drawings. The same or similar components may be designated by the same or similar reference numerals although they are illustrated in different drawings. Detailed descriptions of constructions or processes known in the art may be omitted to avoid obscuring the subject matter of the present invention

Embodiments of the present invention provide a method and an apparatus for dividing an input message into N segments to perform CRC in a communication system.

An information message to be transmitted is first divided into M segments. Assuming the length of each segment is Mᵢ, a message polynomial m(x) of Equation (1) may be expressed as in Equation (4) below.

$$m ( x ) = {\sum }_{i = 0}^{M - 1} {m}_{i} ( x ) {x}^{( k - {\sum }_{j = 0}^{i} {M}_{j} )} \qquad ( 4 )$$

In Equation (4), mᵢ(x) is a sub-message polynomial forming a message polynomial m(x), and represents a message polynomial of each information message divided into M segments.

A comparison of Equation (1) with Equation (4) shows that the m(x) is a polynomial whose degree is k and mᵢ(x) is a polynomial whose degree is Mᵢ with relation of

$$k = {\sum }_{i = 0}^{M - 1} {M}_{i} .$$

That is, m(x), which is a high degree message polynomial, may be expressed in the form of sum of products of low degree message polynomials and shift factors.

Equation (5) represents a basic identical equation of a Residue Number System (RNS).

$${\vert {\sum }_{j = 1}^{k} {X}_{j} \vert}_{{m}_{i}} = {\vert {\sum }_{j = 1}^{k} {\vert {X}_{j} \vert}_{{m}_{i}} \vert}_{{m}_{i}} \qquad ( 5 )$$

An examination of Equation (5) shows that a result of a modulo operation for X₁+ . . . +Xₖ is identical to a result obtained by summing all results of modulo operations for X₁, . . . , Xₖ, and then performing a modulo operation on the summed result again.

In an embodiment of the present invention, Equation (5) is extended to the GF. Specifically, since a process of obtaining a CRC code on the GF is similar to a method of calculating a remainder obtained by dividing a message polynomial by a generator polynomial, Equation (6) below is obtained by extending Equation (5) representing a modulo operation of the RNS to a polynomial, and then applying the Equation (5) to Equation (4).

$$m ( x ) mod g ( x ) = {\sum }_{i = 0}^{M - 1} ( {m}_{i} ( x ) {x}^{( k - {\sum }_{j = 0}^{i} {M}_{j} )} ) mod g ( x ) \qquad ( 6 )$$

Equation (6) shows that a CRC code of a message polynomial m(x) is identical to a sum of respective CRC codes of M divided sub-message polynomials mᵢ(x).

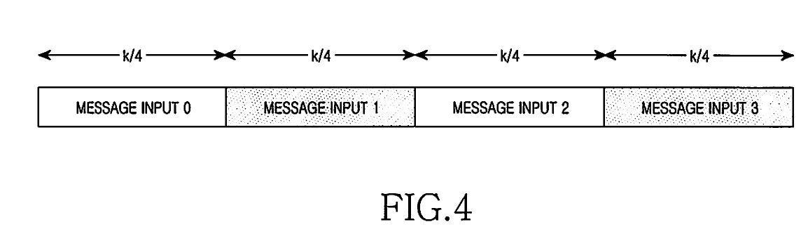

FIG. 4 is a diagram illustrating an information message divided into four segments, according to an embodiment of the present invention. Assuming that an information message to be transmitted, whose entire length is k, is divided into four segments, i.e, four sub-messages, and the lengths of respective sub-messages Mᵢ are the same (k/4), a message polynomial of Equation (4) may be expressed as in Equation (7) below.

m(x)=m₀(x)x^{3k/4}+m₁(x)x^{2k/4}+m₂(x)x^{k/4}+m₃(x)

{m₀(x)=mₖ₋₁x^{k/4-1}+mₖ₋₂x^{k/4-2}+ . . . +m_{3k/4}m₁(x)=m_{3k/4-1}x^{k/4-1}+m_{3k/4-2}x^{k/4-2}+ . . . +m_{k/2}m₂(x)=m_{k/2-1}x^{k/4-1}+m_{k/2-2}x^{k/4-2}+ . . . +m_{k/4}m₃(x)=m_{k/4-1}x^{k/4-1}+m_{k/4-2}x^{k/4-2}+ . . . +m₀} (7)

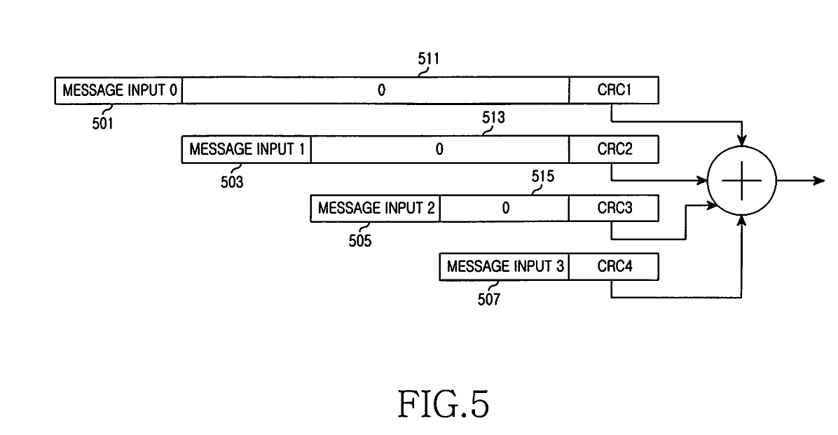

Therefore, when the relation of Equation (6) is applied to the message polynomial m(x) and each sub-message polynomial mᵢ(x) shown in Equation (7), a CRC code may be obtained as illustrated in FIG. 5.

FIG. 5 is a diagram illustrating a technique of generating a CRC code of an entire information message using divided segments, according to an embodiment of the present invention. The same result as a CRC code of an information message m(x), which is to be originally transmitted, may be obtained by adding message ‘0’ (511, 513, 515), which corresponds to each of sub-messages 501, 503, 505, and 507 multiplied by power of x to perform a CRC encoding on each of the sub-messages, and summing CRCs generated as a result thereof using a GF (2) adder. Here, the message ‘0’ represents for degree of corresponding to each of the sub-message._{—}

As described above, an embodiment of the present invention proposes a technique of obtaining a CRC code of an information message to be originally transmitted by dividing the information message to be transmitted into M sub-messages, and then obtaining and summing CRC codes of respective sub-messages.

However, when the above-described technique is used, since ‘0’ is added to each sub-message, the same time delay as the time delay of the conventional parallel CRC encoder/decoder is generated.

Therefore, an embodiment of the present invention obtains a new relation between a CRC code of an original information message and CRCs of sub-messages based on an identical equation shown in Equation (8) below to reduce a delay time caused by CRC encoding/decoding.

Equation (8) represents another identical equation of an RNS.

$${\vert {\prod }_{j = 1}^{k} {X}_{j} \vert}_{{m}_{i}} = {\vert {\prod }_{j = 1}^{k} {\vert {X}_{j} \vert}_{{m}_{i}} \vert}_{{m}_{j}} \qquad ( 8 )$$

An examination of Equation (8) shows that a result of a modulo operation for X₁× . . . ×Xₖ is identical to a result obtained by multiplying all results of modulo operations for X₁, . . . , Xₖ, and then performing a modulo operation on the multiplied result again.

When Equation (8) is extended to a polynomial and applied to Equation (6), Equation (9) below is obtained.

$$m ( x ) mod g ( x ) = {\sum }_{i = 0}^{M - 1} ( \begin{matrix}( {m}_{i} ( x ) mod g ( x ) ) \\ ( {m}_{i} ( x ) {x}^{( k - {\sum }_{j = 0}^{i} {M}_{j} )} mod g ( x )\end{matrix} ) mod g ( x ) \qquad ( 9 )$$

An examination of Equation (9) shows that a CRC code of a message polynomial m(x), which can be expressed in terms of products of factor polynomials, is identical to a CRC code obtained again for products of CRC codes of the factor polynomials.

When Equation (9) is applied to Equation (7), Equation (10) below is obtained.

C[m(x)]=C[C[m₁(x)]C[x^{3k/4}]]+C[C[m₂(x)]C[x^{k/2}]]+C[C[m₃(x)]C[x^{k/4}]]+C[m₄(x)] (10)

In Equation (10), a function C[•] represents CRC encoding, and multiplication and addition represent GF polynomial multiplication and GF polynomial addition, respectively.

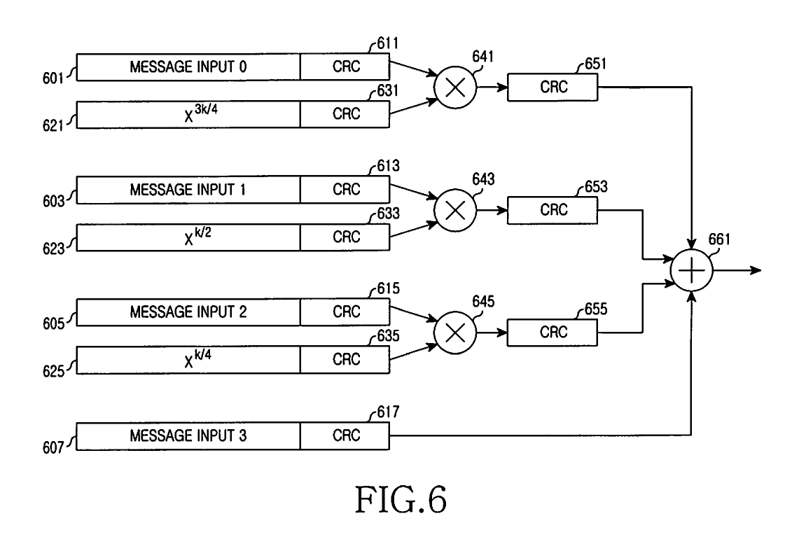

FIG. 6 illustrates a technique of obtaining a CRC code of an information message m(x) to be transmitted on the basis of Equation (10), using divided segments, according to another embodiment of the present invention. Referring to FIG. 6, CRC codes 611, 613, 615, and 617 of sub-messages mᵢ(x) 601, 603, 605, and 607, which are obtained by dividing an information message to be transmitted to four segments, are multiplied by CRC codes 631, 633, and 635 of shift factors 621, 623, and 625 expressed in terms of powers of x using GF(2) multipliers 641, 643, and 645. Since results of the GF multipliers 641, 643, and 645 have higher degrees than those of generator polynomials g(x), CRC encoding is performed on the multiplied results one more time, and then the resulting CRC codes 651, 653, and 655 are summed using a GF adder 661, so that a final CRC code is obtained. At this point, the final CRC code becomes a CRC code of the information message to be transmitted.

As described above, since a CRC code of an entire information message is obtained by dividing the information message into N segments and then obtaining CRC codes of respective divided segments, a clock of k/M+2M is required.

A technique for performing CRC decoding is described below based on the above description. A decoder of DownLink-Shared CHannel (DL-SCH) of Long Term Evolution (LTE) is illustrated by way of example. Note that the above-described CRC encoding/decoding technique is applicable to communication systems using other schemes.

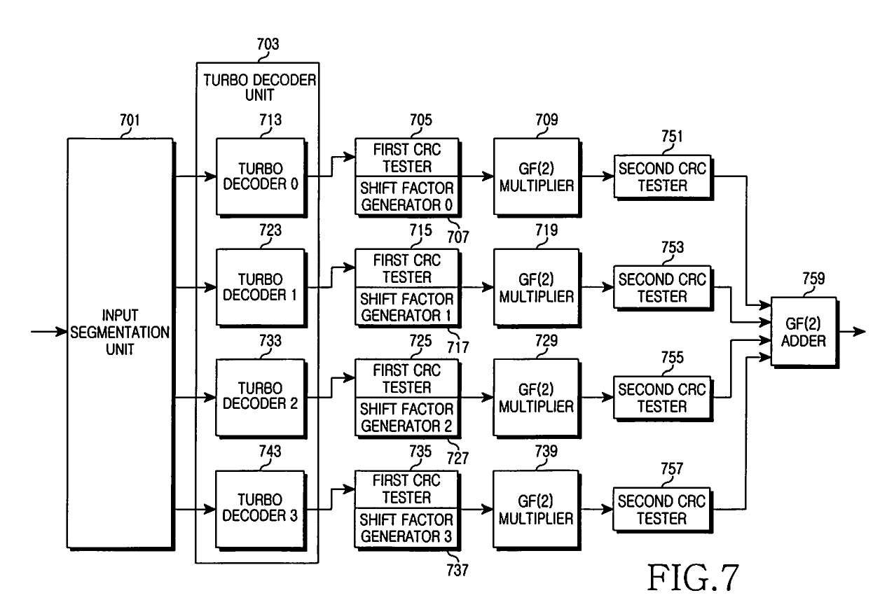

FIG. 7 is a block diagram illustrating a CRC decoder in a communication system, according to an embodiment of the present invention.

Referring to FIG. 7, the CRC decoder includes an input segmentation unit 701, a turbo decoder unit 703, N first CRC testers 705, 715, 725, and 735, N shift factor generators 707, 717, 727, and 737, N GF(2) multipliers 709, 719, 729, and 739, N second CRC testers 751, 753, 755, and 757, and a GF(2) adder 759.

The input segmentation unit 701 divides an input Log Likelihood Ratio (LLR) into N segments and provides the N segments to the turbo decoder unit 703.

The turbo decoder unit 703 includes N turbo decoders 713, 723, 733, and 743. The turbo decoders 713, 723, 733, and 743 perform turbo decoding on the N segments, respectively, provided from the input segmentation unit 701, and outputs the turbo-decoded segments to the N first CRC testers 705, 715, 725, and 735, respectively. The turbo decoder of the LTE DL-SCH may divide a code block and decode the divided code block using a Quadrature Polynomial Permutation (QPP) interleaver in order to support a high-speed information transmission rate.

The N first CRC testers 705, 715, 725, and 735 receive the turbo-decoded segments from the turbo decoders 713, 723, 733, and 743, respectively, to perform CRC tests.

The N shift factor generators 707, 717, 727, and 737 perform CRC tests on shift factors as shown in Equation (9). When the length of a divided segment is known, a CRC code of a shift factor may be obtained in advance regardless of the content of an input message. The shift factor generators 707, 717, 727, and 737 may obtain a CRC code of a relevant shift factor by testing a CRC code corresponding to the length of a relevant segment in a table stored in advance.

The N GF(2) multipliers 709, 719, 729, and 739 perform polynomial multiplication on CRC codes of respective segments obtained by the first CRC testers 705, 715, 725, and 735, respectively, and CRC codes of respective shift factors obtained by the shift factor generators 707, 717, 727, and 737, respectively.

The N second CRC testers 751, 753, 755, and 757 perform CRC tests again on polynomial multiplication results provided from the N GF(2) multipliers 709, 719, 729, and 739, respectively.

The GF(2) adder 759 obtains a final CRC code by performing polynomial addition on N CRC codes obtained by the N second CRC testers 751, 753, 755, and 757, respectively.

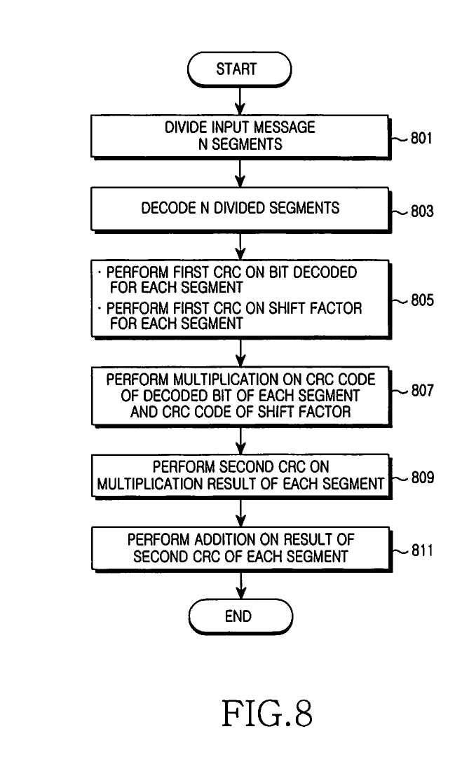

FIG. 8 illustrates a procedure of performing CRC decoding in a communication system, according to an embodiment of the present invention.

Referring to FIG. 8, in step 801, a CRC decoder divides an input LLR into N segments, and in step 803, the CRC decoder performs turbo decoding on each divided segment.

In step 805, the CRC decoder performs a CRC test on each bit turbo-decoded for each segment, and performs a first CRC test on a shift factor of each segment. When the length of the divided segment is known, the CRC decoder may obtain a CRC code of the shift factor regardless of contents of the input message.

In step 807, the CRC decoder performs polynomial multiplication on a CRC code of each segment and a CRC code of a corresponding shift factor using a GF(2) multiplier, and in step 809, the CRC decoder performs second CRC on a multiplication result of each segment.

In step 811, the CRC decoder performs polynomial addition on the result obtained by performing the second CRC on the multiplication result of the each segment, using a GF(2) adder to obtain a final CRC code. The CRC decoder then ends the operation according to an embodiment of the present invention.

Embodiments of the present invention may shorten a delay time caused by CRC encoding/decoding by dividing an input signal into N segments and performing a CRC on the divided segments in a communication system. The CRC tester, the GF multiplier, and the GF adder used for the CRC encoding/decoding may be formed of shift registers and logic gates, so that embodiments of the present invention may be realized using a small amount of hardware.

Although the invention has been shown and described with reference to certain preferred embodiments thereof, it will be understood by those skilled in the art that various changes in form and detail may be made therein without departing from the spirit and scope of the invention as defined by the appended claims and their equivalents. Therefore, the scope of the present invention should not be limited to the above-described embodiments but should be determined by not only the appended claims but also the equivalents thereof.

What is claimed is:

1. A method for performing a Cyclic Redundancy Check (CRC) in a communication system, the method comprising the steps of:
dividing an input message into a predetermined number of segments;
performing the CRC on each segment to generate a CRC code of each segment; and
performing polynomial addition on the CRC codes of the predetermined number of segments to obtain a CRC code of the input message.

2. The method of claim 1, wherein generating the CRC code of each segment comprises:
generating a CRC code of the each segment;
generating a CRC code of a shift factor for each segment determined by a length of each segment;
performing polynomial multiplication on the CRC code of each segment and the CRC code of a corresponding shift factor; and
generating a CRC code of each polynomial multiplication result.

3. The method of claim 1, further comprising turbo-decoding each segment using a predetermined number of turbo decoders.

4. The method of claim 1, wherein the CRC code of the input message is represented by:
$$m ( x ) mod g ( x ) = {\sum }_{i = 0}^{M - 1} ( \begin{matrix}( {m}_{i} ( x ) mod g ( x ) ) \\ ( {m}_{i} ( x ) {x}^{( k - {\sum }_{j = 0}^{i} {M}_{j} )} mod g ( x )\end{matrix} ) mod g ( x )$$
where m(x) represents the input message, mᵢ(x) represents each segment, x^{(•)} is a shift factor of each segment, and M is the predetermined number of segments.

5. An apparatus for performing a Cyclic Redundancy Check (CRC) in a communication system, the apparatus comprising:
a segmentation unit for dividing an input message into a predetermined number of segments;
a CRC generator for each segment, for generating a CRC code of each segment; and
a Galois Field (GF) adder for performing polynomial addition on the CRC codes of the predetermined number of segments to obtain a CRC code of the input message.

6. The apparatus of claim 5, wherein the CRC generator for each segment comprises:
N first CRC units for generating CRC codes of respective segments;
N shift factor generators for generating CRC codes of shift factors for the respective segments determined through lengths of the respective segments;
N GF multipliers for performing polynomial multiplication on the CRC codes of the respective segments and the CRC codes of corresponding shift factors; and
N second CRC units for generating CRC codes of respective polynomial multiplication results.

7. The apparatus of claim 5, further comprising N turbo decoders for turbo-decoding the respective segments.

8. The apparatus of claim 5, wherein the CRC code of the input message is represented by:
$$m ( x ) mod g ( x ) = {\sum }_{i = 0}^{M - 1} ( \begin{matrix}( {m}_{i} ( x ) mod g ( x ) ) \\ ( {m}_{i} ( x ) {x}^{( k - {\sum }_{j = 0}^{i} {M}_{j} )} mod g ( x )\end{matrix} ) mod g ( x )$$
where m(x) represents the input message, mᵢ(x) represents each segment, x^{(•)} is a shift factor of each segment, and M is the predetermined number of segments.
